(19) United States
(12) Patent Application Publication
(10) Pub. No.: US 2009/0166675 A1
(43) Pub. Date: Jul. 2, 2009

(54) STRAIN ENGINEERING IN SEMICONDUCTOR COMPONENTS

(75) Inventor: Mahalingam Nandakumar, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/346,458

(22) Filed: Dec. 30, 2008

Related U.S. Application Data
(60) Provisional application No. 61/018,104, filed on Dec. 31, 2007.

(51) Int. Cl. H01L 29/737; H01L 21/265; H01L 21/337

(52) U.S. Cl. 257/190; 438/530; 438/186; 257/E29.193; 257/E21.334; 257/E21.445

(57) ABSTRACT

This disclosure relates to strain engineering to improve the performance of semiconductor components that include a strained region of the semiconductor substrate. The disclosure involves the amorphization of the target region and the recrystallization of the atomic lattice whilst imposing a strain on the region. The region so formed will form a strained lattice, wherein the strain is uniformly distributed throughout the region, and which retains the intrinsic strain even if the source of the mechanical strain is removed. The disclosure includes methods for forming semiconductor substrates having strained regions (such as semiconductor components having a strained channel region) and semiconductor components formed thereby, as well as variations having various properties and advantages.

### PRIORITY CLAIM

This patent application claims priority under 35 U.S.C. §119(a), inter alia, to U.S. patent application No. 61/018,104, filed Dec. 31, 2007, also entitled “Strain Engineering in Semiconductor Components.”

### FIELD

This disclosure relates generally to the field of semiconductor components, and more particularly to the advantageous use of mechanical strain in the formation of semiconductor components.

### BACKGROUND

Integrated semiconductor circuits are built through an intricate process of creating and interconnecting, on a semiconductor wafer, a multitude of devices comprising layers having various electromechanical properties. The process begins with the provision of a silicon wafer and the doping of selected areas. The doped areas are often electrically isolated from one another in order to prevent unintended conductivity between areas, e.g., by forming an isolation structure, such as a trench etched between two and filled with a dielectric material.

After formation of the isolation trench, a layer of controllably conductive material is selectively deposited to form a gate that will span a plurality of electrically active areas. The electrically active areas are doped with doped with a second dopant (e.g., an n-type dopant may be used to form electrically active areas in an area that has been generally p-type doped.) The doping is performed such that the gate spans a region of the semiconductor substrate that is disposed between the electrically active areas but is essentially free of the second dopant that is used to form the electrically active areas. The channel ordinarily provides a high resistance between the electrically active areas; but when the gate is energized, the resistance of the channel drops, thereby forming a high conductance path between the source region and the drain region. In this manner, the gate may be operated as a switch to control the conductivity of the channel.

After doping and forming the gate, a silicide layer may be formed over the active areas and the gate, which may serve as an etch-stop layer and/or reduce the resistivity in the interface of the underlying structures with metallization contacts. A layer of dielectric material is then deposited over the wafer and manufactured devices, which may serve to protect and electrically insulate the devices. The dielectric layer is often preceded with a liner layer, which often comprises a nitride. Contact vias are selectively etched through the dielectric material that provide access to each gate and active transistor area. The contact vias are filled with one or more conductive metals, and the surface contact points for each metallized contact via are interconnected with other devices, for example, to produce a fully interconnected integrated circuit.

### SUMMARY

The following presents a simplified summary of the disclosure in order to provide a basic understanding of some aspects of the disclosure. This summary is not an extensive overview of the disclosure. It is intended neither to identify key or critical elements of the disclosure nor to delineate the scope of the disclosure. Rather, its primary purpose is merely to present one or more concepts of the disclosure in a simplified form as a prelude to the more detailed description that is presented later.

As discussed hereinabove, this disclosure relates to the field of semiconductor devices formed on a semiconductor wafer. FIG. 1 illustrates an exemplary device of this type, where the device 10 is formed on a semiconductor substrate 12, such as through the process described hereinabove. A region 14 of the semiconductor substrate 12 is implanted with a dopant that renders the region 14 electrically conductive in such a manner as to insulate the electrical properties of the component 10 formed thereupon. For example, if the component 10 is intended as an NMOS device, the region 14 is doped with a p-type dopant that will electrically insulate the operation of the n-type component 10. The doped region 14 may also be insulated from adjacent doped regions (not shown) by forming one or more isolation structures therebetween, e.g., a LOCOS structure or (as illustrated in FIG. 1) a silicon trench isolation structure 16.

The exemplary component 10 of FIG. 1 comprises a source region 18, formed by doping a region of the semiconductor substrate 12 with a dopant of the desired device type (e.g., an n-type dopant for an NMOS device.) The source region 18 may be adjacent to a lightly doped source extension region 20, formed by doping a region of the semiconductor substrate 12 with the same dopant as the source region 18, but at a considerably lower concentration and restricted to a considerably lower implantation depth. The component 10 also comprises a drain region 22, adjacent to a drain extension region 24, formed in a similar manner and having similar properties. Between the source region 18 (including the source extension region 20) and the drain region 22 (including the drain extension region 24) is the channel 26, comprising a region of the semiconductor substrate 12 that is relatively free of the dopant used in the source and drain regions 18, 22. The exemplary component 10 also comprises a gate formed over the semiconductor substrate and spanning the source region 18 and the drain region 22, formed such that an electric current passed through the gate induces electrical conductance in the channel 26. The gate in this exemplary component 10 comprises a strain-imposing layer 28 overlaying the channel 26 and underlaying a gate electrode 30.

The configuration and formation characteristics of the elements of a device are significantly determinative of the resulting performance of the device, e.g., the threshold voltage for activating the channel and the switching rate of the device. One such characteristic is the existence of mechanical strain on the region of the semiconductor substrate comprising the channel of the device, which serves to increase the carrier mobility across the channel, thereby improving the switching rate of the device. It may be desirable to impose a tensile mechanical strain while forming NMOS devices, and to impose a compressive mechanical strain while forming PMOS devices.

Many techniques exist for imposing strain on the channel of a semiconductor device, such as by forming a strain-imposing layer over the channel. The strain may also be imposed by adjusting the formation of an isolation structure, such as STI isolation or LOCOS isolation, to impose strain on the layer. While these techniques impose strain on the silicon lattice comprising the channel of the component, the strain so imposed is external to the lattice. These techniques may therefore present two disadvantages: the externally exerted strain may be unevenly applied across the channel (e.g., more strongly imposed at the edges of the channel nearest the strain-imposing structure, and more weakly imposed in other portions of the channel); and the externally imposed strain is dependent on the continued imposition by the strain-imposing structure(s).

An alternative technique, as presented in this disclosure, is to incorporate the mechanical strain as part of the crystalline lattice structure of the channel. This effect may be achieved by amorphizing the crystalline lattice of the channel, and recrystallizing the lattice of the channel while applying the desired mechanical strain (either tensile or compressive.) The atomic bonds of the resulting crystalline lattice will be formed to incorporate the imposed strain throughout the lattice, thereby retaining the strain as an intrinsic property of the crystalline lattice even if the externally imposed strain is then relaxed. Additionally, the reformation of the crystalline lattice in the presence of strain may evenly incorporate the strain throughout the channel, thereby improving the uniform distribution of the intrinsic strain throughout the channel region.

To the accomplishment of the foregoing and related ends, the following description and annexed drawings set forth in detail certain illustrative aspects and implementations of the disclosure. These are indicative of but a few of the various ways in which one or more aspects of this disclosure may be employed. Other aspects, advantages, and novel features of the disclosure will become apparent from the following detailed description of the disclosure when considered in conjunction with the annexed drawings.

### BRIEF DESCRIPTION OF THE DRAWINGS

FIG. 1 is an elevation view in section of an exemplary semiconductor component formed on a semiconductor substrate.

FIG. 2 is a flowchart illustrating an exemplary method in accordance with this disclosure.

FIGS. 3A-3D are elevation views in section of various stages of formation of a semiconductor substrate formed in accordance with this disclosure.

FIG. 4 is a flowchart illustrating another exemplary method in accordance with this disclosure.

FIGS. 5A-5D are elevation views in section of various stages of formation of a semiconductor component formed on a semiconductor substrate formed in accordance with this disclosure.

### DETAILED DESCRIPTION

One or more aspects of this disclosure are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of this disclosure. It may be evident, however, to one skilled in the art that one or more aspects of this disclosure may be practiced with a lesser degree of these specific details. In other instances, well-known structures and devices are shown in block diagram form in order to facilitate describing one or more aspects of this disclosure.

This disclosure relates to a strain engineering technique for use in the fabrication of semiconductor components. As discussed herein, the technique involves amorphizing a region of a semiconductor substrate, and then recrystallizing the region while imposing a mechanical strain on the region. When applied to form a region comprising a channel in a semiconductor substrate, the device incorporating the strained channel may exhibit improved performance, such as increased switching rate.

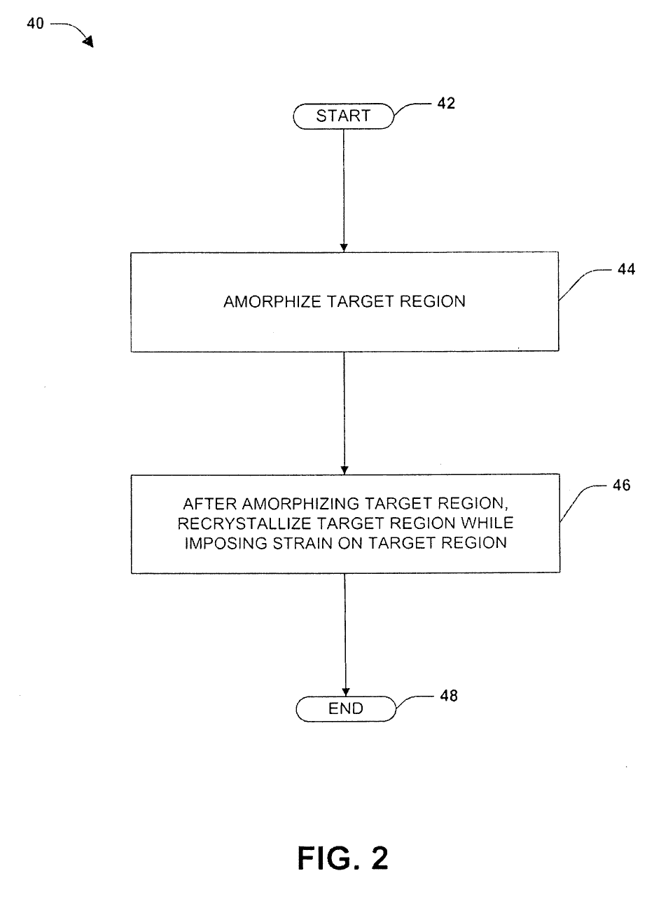

An exemplary method in accordance with this technique is illustrated in FIG. 2 for forming a strained region of a semiconductor substrate. The method 40 begins at 42 and involves amorphizing the target region 44. The amorphizing may be performed by utilizing many techniques known in the art of semiconductor fabrication. As one example, the amorphizing may comprise the placement by ion implantation of an amorphizer in the target region, in which ions of the amorphizer are fired into the target region at high velocity, thereby physically disrupting the regular crystalline lattice structure of the semiconductor substrate in this region.

After amorphizing the target region 44, the method 40 involves recrystallizing 46 the target region while imposing strain on the target region. One technique for imposing strain on the target region during recrystallization is to form one or more strain-imposing structures near the region, e.g., STI or LOCOS isolation structures or by depositing a tensile/compressive strain imposing nitride layer over the target region, The recrystallization may be performed by thermally annealing the semiconductor substrate, which provides sufficient energy for the atoms of the semiconductor substrate to reestablish bonds with neighboring atoms, thereby reforming the regular lattice structure of the substrate. The amorphizing 44 and subsequent recrystallizing under strain 46 of the target region causes the targeted region of the semiconductor substrate to form a regular crystalline lattice structure that incorporates the externally imposed strain, and therefore retains the imposed strain even if the externally imposed strain is subsequently relaxed. Upon recrystallizing 46 the target region while imposing the strain on the target region, the method 40 ends at 48.

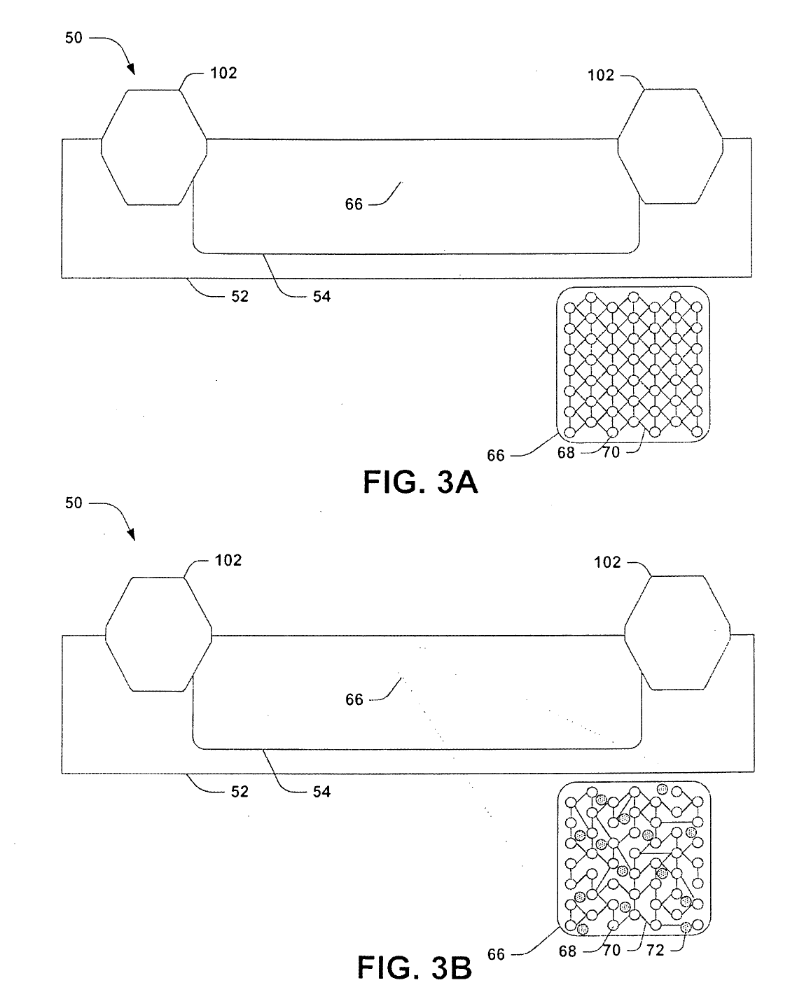

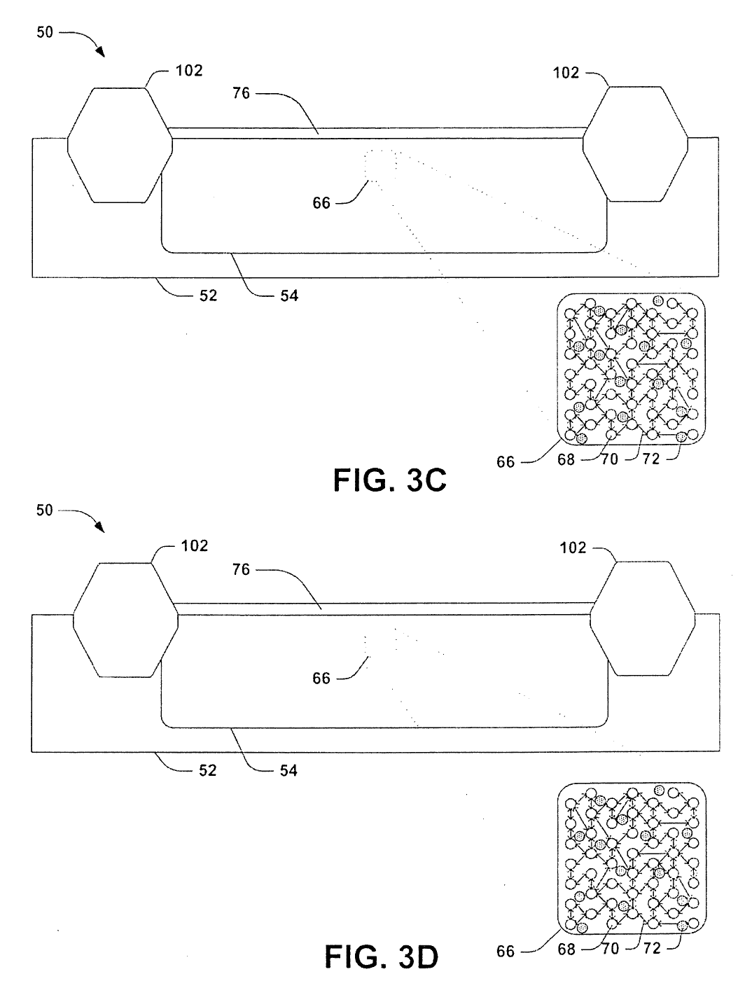

FIGS. 3A-3D illustrate an exemplary use of the exemplary method illustrated in FIG. 2 during various stages of formation of an exemplary semiconductor region 50. In these figures, a portion 66 of the semiconductor region 50 is illustrated in exploded detail, in which the silicon atoms 68 are interconnected with atomic bonds 70 that form a regular crystalline lattice. It will be appreciated that the crystalline lattice shown in FIGS. 3A-3D is presented in overly simplified form, and is intended not as an actual depiction of the physical structure of such a crystalline lattice, but only to illustrate the concepts discussed herein.

Turning first to FIG. 3A, an exemplary semiconductor region 50 is illustrated in an early stage of formation, comprising a semiconductor substrate 52 having a doped region 54, which may comprise a dopant conferring electrical properties opposite those of the planned semiconductor component, e.g., doped with a p-type dopant in order to support an NMOS component. Alternatively, the doped region 54 may only exist as a target doped region that has been designated for later placement of such a dopant. FIG. 3A also illustrates a silicon trench isolation structure 102 on each side of the doped area 54, which together electrically insulate the doped area 54 of the semiconductor region 50 from adjacent components and doped areas (not shown.)

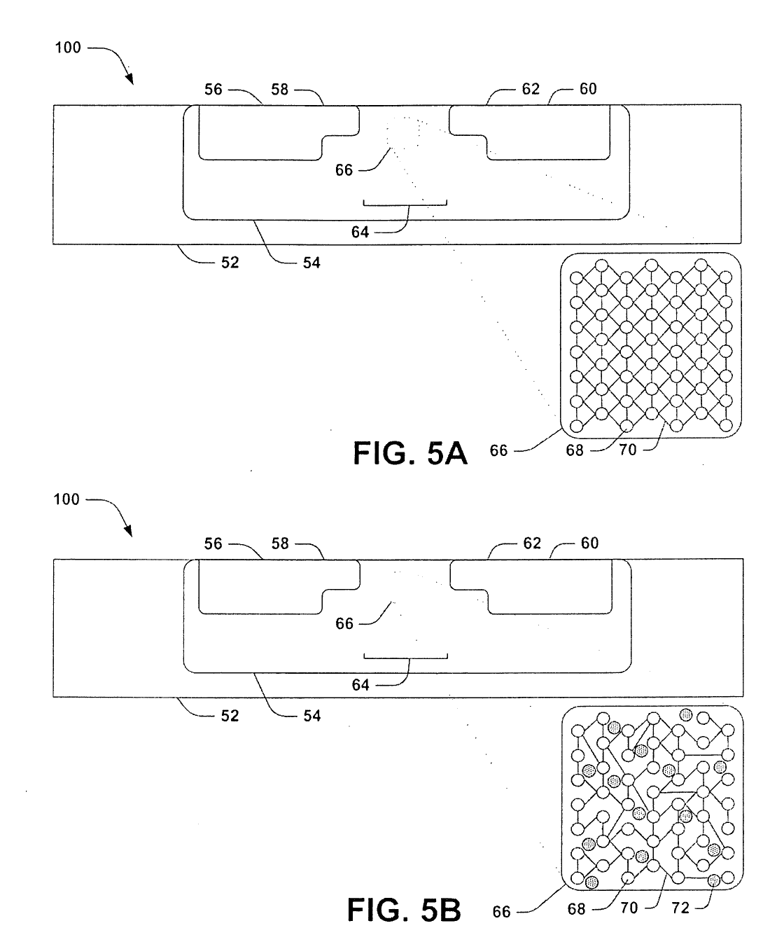

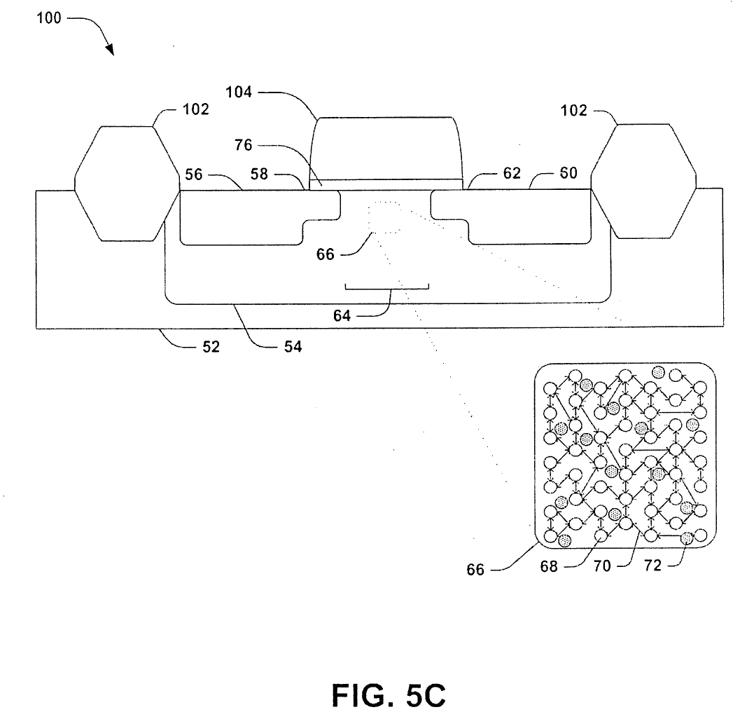

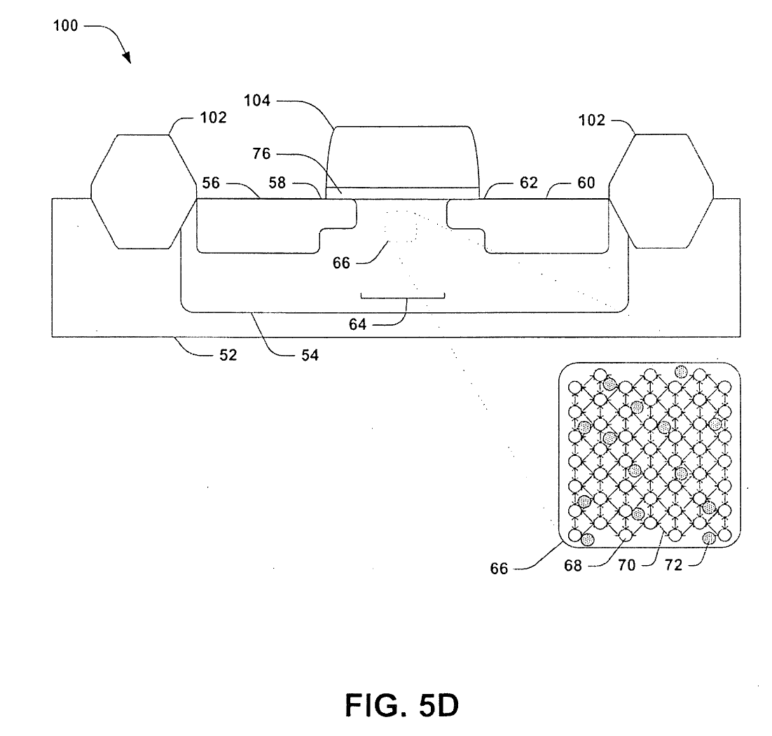

FIG. 3B illustrates the exemplary semiconductor region 50 at a later stage of development, again presenting a semiconductor substrate 52 having a doped region 54. In this stage, at least a portion of the doped region 54 has been amorphized, such that the atomic bonds between the silicon atoms in the doped region 54 of the semiconductor substrate 52 have been randomly broken and reformed, thereby disrupting the regular crystalline lattice structure of the silicon atoms. This concept is illustrated in the exploded view 66 of a portion of the doped region 54, in which the silicon atoms 68 of the semiconductor substrate are still interconnected by atomic bonds 70, but these bonds 70 have been redistributed to create an amorphous pattern. In the exemplary semiconductor substrate of FIG. 5B, this amorphization is achieved by the ion implantation of an amorphizer 72, in which ions of the amorphizer 72 are fired into the doped region 54 at high velocity, thereby physically disrupting the regular crystalline lattice bonding of the silicon atoms 68. It will be appreciated that the amorphization is not due to the presence of the amorphizer 72 in this portion of the doped region 54, but rather by the physical disruption caused by the ion implantation of the amorphizer 72 into the doped region 54.

FIG. 3C illustrates the exemplary semiconductor region 50 at a still later stage of development, once again presenting a semiconductor substrate 52 having a doped region 54, as well as a silicon trench isolation structure 102 on each side of the doped area 54. The exemplary semiconductor component of FIG. 3C also comprises a strain-imposing layer 76 overlaying the doped region 54 and underlaying a gate electrode 104. As discussed hereinabove, a strain-imposing layer such as illustrated in the exemplary semiconductor region 50 of FIGS. 3C-3D may be formed, e.g., by depositing a silicon nitride or silicon carbide layer over the doped region 54 that imposes a tensile/compressive strain on the doped region 54. It may be appreciated that FIG. 3C illustrates two techniques of imposing strain on the doped region 54, and that strain may be imposed on the doped region 54 by either technique, or by both techniques, and that other techniques for imposing strain may also be used alone or together with the techniques illustrated in FIG. 3C.

As in FIG. 3B, FIG. 3C illustrates an exploded portion 66 of the doped region 54, in which the silicon atoms 68 are interconnected by atomic bonds 70 that form an amorphous pattern, having been disrupted by the ion implantation of the amorphizer 72. In addition, the atomic bonds 70 between the silicon atoms 68 are illustrated as exhibiting the tensile strain imposed on the doped region 54 by the strain-imposing layer 58. While the exploded view 68 illustrates the tensile strain as omnidirectional, it will be appreciated that this illustration serves only to denote the presence of tensile strain, not the particular orientation of the strain exerted on the doped region 54. Depending on the technique selected for imposing strain on the doped region 54, the strain may be imposed unidirectionally, bidirectionally, or in many other configurations.

FIG. 3D illustrates the exemplary semiconductor region 50 at a still later stage of development, once again presenting a semiconductor substrate 52 having a doped region 54. As in FIG. 3C, an exploded portion 66 of the doped region 54 is illustrated, comprising silicon atoms 68 interconnected by atomic bonds 70 and an ion implanted amorphizer 72. In this stage of formation, the silicon atoms 68 of the doped region 54 have been recrystallized during the imposition of strain upon the doped region 54 by the strain-imposing layer 76 and/or the silicon trench isolation structures 102. The recrystallizing may be performed, e.g., by thermally annealing the semiconductor substrate 52, which provides sufficient energy for the atoms of the semiconductor substrate reestablish bonds with neighboring atoms, thereby reforming the regular lattice structure of the substrate. Because the atomic bonds 70 comprising the crystalline lattice structure of the silicon atoms 68 are reformed in the presence of mechanical strain, the bonds that are formed intrinsically embody the mechanical strain (as illustrated by the strained lattice bonds 70 illustrated in FIG. 3D.)

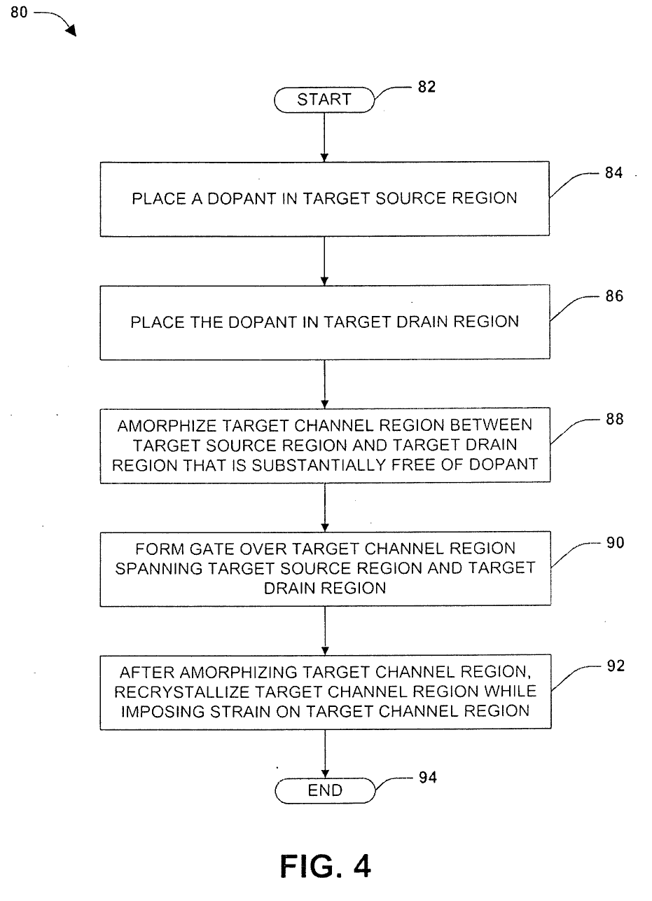

An exemplary use of the method illustrated in FIG. 2 is the formation of a semiconductor component having a strained region, e.g. a transistor having a strained channel. Accordingly, FIG. 4 illustrates an exemplary method of forming a semiconductor component on a semiconductor substrate in accordance with the techniques disclosed herein. The exemplary method 80 begins at 82 and involves placing a dopant in the target source region 84. (The term “target source region” as used herein denotes the region that will be formed so as to function as the source region in the completely formed device. The term “target” is used in similar contexts to denote areas that are treated in particular ways as noted herein, that are designated to have certain traits in the completely formed device, and/or that are designated to function in certain ways in the completely formed device.) As noted herein, the dopant implanted in the target source region is desirably selected in order to confer desired electrical properties on the resulting component; e.g., an n-type dopant may be used to create an NMOS device. The dopant may be placed according to any suitable method; e.g., an ion implantation system may be used to inject ions into the desired portion of the semiconductor substrate at a high velocity. The method 80 also involves placing the dopant in the target drain region 86.

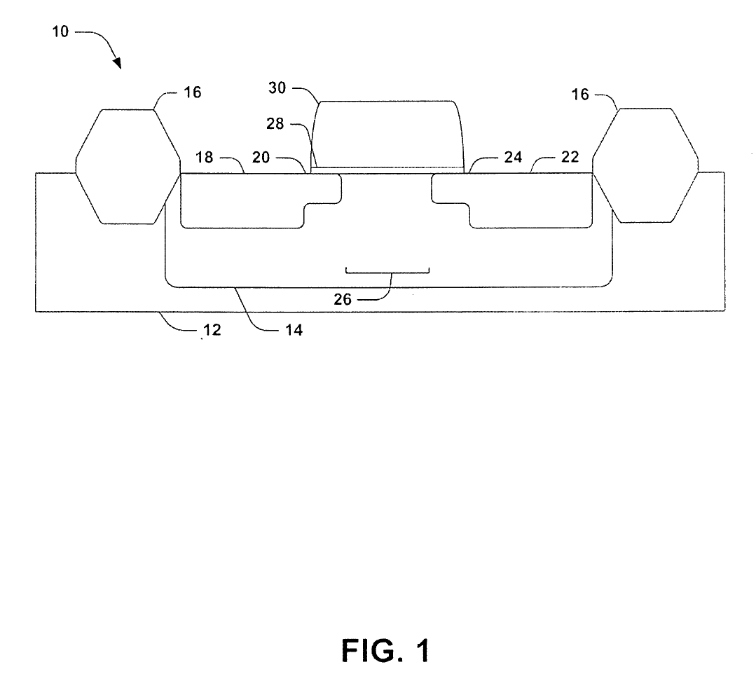

The method 80 of FIG. 4 also involves amorphizing the target channel region, comprising the region between the target source region and the target drain region that is substantially free of dopant. As noted herein, the amorphizing may be performed by any suitable technique, e.g., by placing an amorphizer in the target channel region by ion implantation. The method 80 of FIG. 4 also involves forming a gate 90 over the target channel region that spans the target source region and the target drain region. The gate may be formed as illustrated in FIG. 1, comprising a strain-imposing layer 28 overlaying the channel 26 and underlaying a gate electrode 30, such that providing a current through the gate electrode lowers the resistance and raises the conductivity of the channel 26, thereby forming a high-conductance path between the source region 18 (including the source extension region 20) and the drain region 22 (including the drain extension region 24.) The method 80 of FIG. 4 also involves recrystallizing 92 the target channel region while imposing strain on the target channel region, which occurs after amorphizing the target channel region 86. The semiconductor device formed through this method 80 will exhibit a strained channel region in a semiconductor component that exhibits improved performance; accordingly, the method 80 ends at 94.

It will be appreciated that the exemplary methods illustrated in FIGS. 2 and 4 may be varied in several aspects. As one example, the strain imposed on the target region may be initiated before, after, or even during the amorphizing of the target region (e.g., the target channel region of the semiconductor component formed by the method of FIG. 4.) As another example, strain may be imposed on the target region in many ways, such as by depositing a nitride or carbide layer over the target region, or by forming an isolation structure near the target region, such as an isolation trench created through an STI process, or a silicon oxide structure created through a LOCOS process. Such structures and layers may impose strain on adjacent regions, and the semiconductor engineering process may be configured to recrystallize the target region while strain is imposed on it by such a structure or layer. As still another example, the elements of these methods may be performed in several ordering variations that meet the limitations of the elements (e.g., where the recrystallizing occurs after the amorphizing) and satisfy the ends of these techniques. For instance, in the method illustrated in FIG. 4, the source region and drain region may be doped in a simultaneous doping, or with either doping preceding the other; and these dopings may occur even after forming the gate and/or amorphizing the channel. Many variations may be devised by those of ordinary skill in the art that may be in keeping with this disclosure.

The method illustrated in FIG. 4 may be utilized to form a semiconductor component such as illustrated in FIGS. 5A-5D, which present various stages of formation of an exemplary semiconductor component 10. Turning first to FIG. 5A, an exemplary semiconductor component 100 is illustrated in an early stage of formation, comprising a semiconductor substrate 52 having a doped region 54, which contains a source region 56 having a source extension region 58 and a drain region 60 having a drain extension region 62. At this stage, the doped region 54 may already have been doped with a dopant conferring electrical properties opposite those of the planned semiconductor component, e.g., doped with a p-type dopant in order to support an NMOS component. Alternatively, the doped region 54 may only exist as a target doped region that has been designated for later placement of such a dopant. Similarly, the source region 56 (including the source extension region 58) and the drain region 60 (including the drain extension region 62) may already have been doped with the desired dopant (e.g., an n-type dopant for an NMOS component), or may exist as target regions that have been designated for later doping.

In FIG. 5A, the source region 56 (including the source extension region 58) and the drain region 60 (including the drain extension region 62) are positioned apart, creating a space therebetween that does not and will not contain the dopant placed in the source region 56 and the drain region 60. This space will form the channel 64 of the semiconductor component 100, which will resist the flow of current between the source region 56, 58 and the drain region 60, 62 unless activated by passing current through a gate that will be formed thereupon. In this stage, the channel 64 exists only as a region of the semiconductor substrate, comprising a crystalline lattice of silicon atoms. A portion 66 of the channel 64 is illustrated in exploded detail in FIG. 5A, in which the silicon atoms 68 are interconnected with atomic bonds 70 that form a regular crystalline lattice. It will be appreciated that the crystalline lattice shown in FIGS. 5A-5D is presented in overly simplified form, and is intended not as an actual depiction of the physical structure of such a crystalline lattice, but only to illustrate the concepts discussed herein.

FIG. 5B illustrates the exemplary semiconductor component 100 at a later stage of development, again presenting a semiconductor substrate 52 having a doped region 54 containing a source region 56 having a source extension region 58 and a drain region 60 having a drain extension region 62, designated so as to form a channel therebetween 64. In this stage, the channel 64 has been amorphized, such that the atomic bonds between the silicon atoms in the channel 64 of the semiconductor substrate 52 have been randomly broken and reformed, thereby disrupting the regular crystalline lattice structure of the silicon atoms. This concept is illustrated in the exploded view 66 of a portion of the channel 64, in which the silicon atoms 68 of the semiconductor substrate are still interconnected by atomic bonds 70, but these bonds 70 have been redistributed to create an amorphous pattern. In the exemplary semiconductor substrate of FIG. 5B, this amorphization is achieved by the ion implantation of an amorphizer 72, in which ions of the amorphizer 72 are fired into the channel 64 at high velocity, thereby physically disrupting the regular crystalline lattice bonding of the silicon atoms 68. It will be appreciated that the amorphization is not due to the presence of the amorphizer 72 in this portion 66 of the channel 64, but rather by the physical disruption caused by the ion implantation of the amorphizer 72 into the channel 64.

FIG. 5C illustrates the exemplary semiconductor component 100 at a still later stage of development, once again presenting a semiconductor substrate 52 having a doped region 54 containing a source region 56 having a source extension region 58 and a drain region 60 having a drain extension region 62, designated so as to form a channel therebetween 64. At this later stage of development, a silicon trench isolation structure 102 has been formed on each side of the semiconductor component 100 that electrically insulates the semiconductor component 100 and the doped area 54 from adjacent components and doped areas (not shown.) The exemplary semiconductor component of FIG. 5C also comprises a strain-imposing layer 76 overlaying the channel 64 and underlaying a gate electrode 104. As discussed hereinabove, a strain-imposing layer such as illustrated in the exemplary semiconductor component 100 of FIGS. 5C-5D may be formed, e.g., by depositing a silicon germanium layer over the channel 64 that creates a lattice mismatch with the silicon lattice of the channel 64, thereby imposing a tensile strain on the channel 64.

As in FIG. 5B, FIG. 5C illustrates an exploded portion 66 of the channel 64, in which the silicon atoms 68 are interconnected by atomic bonds 70 that form an amorphous pattern, having been disrupted by the ion implantation of the amorphizer 72. In addition, the atomic bonds 70 between the silicon atoms 68 are illustrated as exhibiting the tensile strain imposed on the channel 64 by the strain-imposing layer 58. While the exploded view 68 illustrates the tensile strain as omnidirectional, it will be appreciated that this illustration serves only to denote the presence of tensile strain, not the particular orientation of the strain exerted on the channel 64. Depending on the technique selected for imposing strain on the channel, the strain may be imposed unidirectionally, bidirectionally, or in many other configurations.

FIG. 5D illustrates the exemplary semiconductor component 100 at a still later stage of development, once again presenting a semiconductor substrate 52 having a doped region 54 containing a source region 56 having a source extension region 58 and a drain region 60 having a drain extension region 62, designated so as to form a channel therebetween 64. At this later stage of development of the exemplary semiconductor device 100, a silicon trench isolation structure 102 has been formed on each side of the semiconductor component 100, and a strain-imposing layer 76 has been formed overlaying the channel 64 and underlaying a gate electrode 104. As in FIG. 5C, an exploded portion 66 of the channel 64 is illustrated, comprising silicon atoms 68 interconnected by atomic bonds 70 and an ion implanted amorphizer 72. In this stage of formation, the silicon atoms 68 of the channel 64 have been recrystallized during the imposition of strain upon the channel 64 by the strain-imposing layer 76. The recrystallizing may be performed, e.g., by thermally annealing the semiconductor substrate 52, which provides sufficient energy for the atoms of the semiconductor substrate reestablish bonds with neighboring atoms, thereby reforming the regular lattice structure of the substrate. Because the atomic bonds 70 comprising the crystalline lattice structure of the silicon atoms 68 are reformed in the presence of mechanical strain, the bonds that are formed intrinsically embody the mechanical strain (as illustrated by the strained lattice bonds 70 illustrated in FIG. 5D.)

If formed in this manner, the atomic bonds 70 of the silicon atoms 68 in the channel 64 will more uniformly incorporate the mechanical strain imposed on the channel 64 during recrystallizing. Additionally, the mechanical strain incorporated in the atomic bonds 70 comprising the crystalline lattice structure of silicon atoms 68 in the channel 64 will be retained even if the externally imposed strain (e.g., the strain imposed by the strain-imposing layer 76) is relaxed. It will be noted that although the amorphizer 72 remains in the channel 64, the silicon atoms 68 may nevertheless form atomic bonds 70 that restore the regular crystalline lattice, because the amorphizing illustrated in FIGS. 5B-5C is caused by the physical and forceful injection of the amorphizer 72 into the channel 64 by ion implantation, and not merely by the presence of the amorphizer 72 in the channel 64.

It will now be appreciated that these techniques may be used to form a semiconductor component that advantageously incorporates strain in the channel for improved device performance (e.g., the semiconductor component illustrated in FIG. 5.) The techniques discussed herein may be used to form a semiconductor component 100 on a semiconductor substrate 52, comprising a source region 56 comprising a dopant; a drain region 60 comprising the dopant; a channel 64, comprising a semiconductor substrate region between the source region 56 and the drain region 60 that is essentially free of the dopant and having a strained crystalline lattice; and a gate 104 formed over the channel 64 and spanning the source region 56, 58 and the drain region 60, 62. It will be further appreciated that this semiconductor component features a strained crystalline lattice comprising the channel region, which may be formed, e.g., by amorphizing the channel and recrystallizing it while imposing strain upon the channel, as discussed herein. The strained crystalline lattice formed thereby is different from an ordinary crystalline lattice upon which strain is externally exerted; moreover, the intrinsic strain of this crystalline lattice may be advantageous for retaining the strain even after relaxation of the external strain, and/or for distributing the strain more uniformly through the lattice than may be achieved by an externally imposed strain. The semiconductor component formed in this manner may additionally feature at least one strain imposing structure configured to impose strain on the channel (e.g., the strain imposing layer 76 formed over the channel 66 of the semiconductor component 100 illustrated in FIG. 5D); alternatively, the strain imposing structure may be removed after the channel is recrystallized, since the strain imposed thereby will have been incorporated in the reformed lattice of the channel during recrystallizing.

Having described some exemplary methods that may be performed in accordance with this disclosure, and having described and illustrated some exemplary semiconductor components that may be formed thereby, this disclosure now presents some variations on the elements of the technique. These variations may be included in the methods disclosed herein to yield additional properties and advantages, and may be included in the formation of semiconductor components created thereby having additional properties and advantages.

As noted herein, the amorphizing of the target region (e.g., the target channel region of the method of FIG. 4, and of the channel 64 of the semiconductor component illustrated in FIG. 5D) may be carried out by ion implantation of an amorphizer, in which ions of the amorphizer are fired at the desired areas of the semiconductor substrate at high velocity. Similarly, semiconductor components formed in this manner may be achieved that comprise an amorphizing species in the channel. In order to perform the amorphizing in this manner, it may be desirable to select an amorphizing species that will not alter the electrical properties of the strained region. Silicon may be desirable for its electrical inertness (in light of the composition of the channel region as silicon), but its comparatively small size may limit the degree of amorphization achieved thereby. Germanium may be desirable for its larger size and more significant amorphization, but may interfere with the formation of oxidized layers above the channel. The intrinsically inert properties of argon may yield a suitable amorphizer, but its light size may again limit the degree of amorphization. Those of ordinary skill in the art will be able to choose among these and other available amorphizers in light of the operating parameters of the fabrication process while utilizing the techniques described herein.

The imposition of strain on the target region (e.g., imposing strain on the target channel region while recrystallizing 62 in FIG. 4, and imposing strain on the channel 64 of FIGS. 5C-5D) may be achieved in many ways. As one example, a strain imposing structure may be formed on the semiconductor substrate that is configured to impose strain on the target area. For instance, and as illustrated in FIGS. 5C-5D, a strain imposing layer 58 may be formed over the channel 64 by depositing a layer of silicon germanium over the channel. This layer interacts with the silicon lattice comprising the channel 64 to form a continued lattice structure, but the lattice geometry of the silicon germanium in the strain imposing layer 58 differs from the lattice geometry of the underlying silicon of the channel 64. This lattice mismatch results in a tensile strain exerted on the channel 64, which may improve the device performance in NMOS devices incorporating such a channel. Other techniques for imposing strain exist, such as (e.g.) forming one or more strain-imposing layers over the channel, forming one or more strain-imposing layers under the channel, and forming one or more strain-imposing structures laterally proximate to the channel. Those of ordinary skill in the art will be able to devise many techniques for imposing strain on the target region while utilizing the techniques described herein.

The recrystallization of the target region (e.g., the recrystallization of the target channel region 62 in the method of FIG. 4, or the recrystallization of the channel 64 in the semiconductor component 100 of FIG. 5D) may be achieved in many ways. It is noted herein that “recrystallization” does not necessarily refer to crystalline growth, or to a chemical state change, but to the reformation of the regular atomic bond structure of the silicon atoms of the semiconductor substrate, following an amorphization of these atomic bonds. One common technique for performing this recrystallization is thermally annealing the semiconductor substrate, e.g., by exposing the semiconductor substrate to a flash lamp, an arc lamp, or a heating laser, and rapidly heating the semiconductor substrate above 1,040° C. for a short period of time. It is advantageous that such a thermal anneal is commonly included in the semiconductor fabrication process in order to activate the dopants of the source region (including the source extension region) and the drain region (including the drain extension region.)

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (assemblies, elements, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, “exemplary” as utilized herein merely means an example, rather than the best.

What is claimed is:

1. A method of straining a target region of a semiconductor substrate, the method comprising:
amorphizing the target region, and
after amorphizing the target region, recrystallizing the target region while imposing strain on the target region.

2. The method of claim 1, the recrystallizing comprising thermally annealing the semiconductor substrate.

3. The method of claim 1, imposing strain on the target region comprising:
before recrystallizing, forming a strain imposing structure configured to impose strain on the target region.

4. The method of claim 3, the strain imposing structure comprising at least one of:
a strain imposing layer formed over the target region;
a strain imposing layer formed under the target region; and
a strain imposing structure formed laterally proximate to the target region.

5. The method of claim 1, the amorphizing comprising implanting an amorphizer in the target region.

6. The method of claim 5, the amorphizer comprising at least one of silicon, germanium, and argon.

7. The method of claim 1, the strain imposed on the target region initiated after amorphizing the target region.

8. The method of claim 1, the strain imposed on the target region initiated before amorphizing the target region.

9. A semiconductor substrate comprising a strained region formed according to the method of claim 1.

10. A method of forming a semiconductor component on a semiconductor substrate, the method comprising:
placing a dopant in a target source region of the semiconductor substrate;
placing the dopant in a target drain region of the semiconductor substrate;
amorphizing a target channel region of the semiconductor substrate between the target source region and the target drain region that is substantially free of the dopant;
forming a gate over the target channel region spanning the target source region and the target drain region; and
after amorphizing the target channel region, recrystallizing the target channel region while imposing strain on the target channel region.

11. The method of claim 10, the recrystallizing comprising thermally annealing the semiconductor substrate.

12. The method of claim 10, the amorphizing comprising implanting an amorphizer in the target channel region.

13. The method of claim 12, the amorphizer comprising at least one of silicon, germanium, and argon.

14. The method of claim 10, the strain imposed on the target channel region comprising: before the recrystallizing, forming a strain imposing structure configured to impose strain on the target channel region.

15. The method of claim 14, the strain imposing structure comprising at least one of:
a strain imposing layer formed over the target channel region;
a strain imposing layer formed under the target channel region; and
a strain imposing structure formed laterally proximate to the target channel region.

16. A semiconductor component having a strained channel formed according to the method of claim 10.

17. A semiconductor component formed on a semiconductor substrate, comprising:
a source region comprising a dopant;
a drain region comprising the dopant;
a channel, comprising a semiconductor substrate region between the doped source region that is essentially free of the dopant and having a strained crystalline lattice; and
a gate formed over the channel and spanning the source region and the drain region.

18. The semiconductor component of claim 17, the channel amorphized and subsequently recrystallized during the imposition of strain on the channel.

19. The semiconductor component of claim 17, the channel comprising an amorphizer.

20. The semiconductor component of claim 17, comprising: at least one strain imposing structure configured to impose strain on the channel, the semiconductor component of claim 23, the strain imposing structure comprising at least one of:
a strain imposing layer formed over the channel;
a strain imposing layer formed under the channel; and
a strain imposing structure formed laterally proximate to the channel.
